(19) United States
(12) Patent Application Publication
(10) Pub. No.: US 2017/0101306 A1
(43) Pub. Date: Apr. 13, 2017

(54) MICROMECHANICAL COMPONENT HAVING TWO AXES OF OSCILLATION AND METHOD FOR PRODUCING A MICROMECHANICAL COMPONENT

(71) Applicant: Robert Bosch GmbH, Stuttgart (DE)

(72) Inventor: Stefan Pinter, Reutlingen (DE)

(21) Appl. No.: 15/317,231

(22) PCT Filed: May 6, 2015
(86) PCT No.: PCT/EP2015/059893

§ 371 Date: Dec. 8, 2016

(30) Foreign Application Priority Data
Jun. 10, 2014 (DE) 10 2014 211 027.0

(51) Int. Cl. B81B 3/00; G02B 26/10; G02B 7/182; B81C 1/00; G02B 26/08

(52) U.S. Cl. CPC B81B 3/0043; B81C 1/00198; G02B 26/0833; G02B 7/1821; G02B 26/105; B81B 2201/042; B81B 2203/0307; B81B 2203/058; B81B 2203/0118

(57) ABSTRACT

A micromechanical component is described as having a part that is movable relative to a holder. The part is suspended on the holder at least via a suspension structure. Self-oscillations of the suspension structure are inducible such that, relative to the holder, the movable part can be set into a resonant oscillatory movement about a first axis of rotation and into a quasi-static oscillatory movement about a second axis of rotation oriented at an incline to the first axis of rotation by the suspension structure set into the self-oscillations. The movable part is connected directly or via at least one spring to at least one oscillation node point of at least one of the induced self-oscillations of the suspension structure. In addition, a method is described for producing a micromechanical component.

### FIELD OF THE INVENTION

The present invention relates to a micromechanical component. In addition, the present invention relates to a method for producing a micromechanical component.

### BACKGROUND INFORMATION

In German Published Patent Application No. 10 2011 006 598, components are described having a movable part, and methods for operating a component having a movable part are described. In order to move the movable part, in each case at least one subunit of at least one flexible connecting component via which the movable part is connected to a holder is set into a first oscillatory movement along a first axis and into a second oscillatory movement along a second axis oriented so as to be inclined relative to the first axis. This brings it about that the movable part, relative to the holder, is capable of being set into a rotary oscillatory movement about a first axis of rotation and in addition to the rotary oscillatory movement can also be deflected about a second axis of rotation.

### SUMMARY

The present invention creates a micromechanical component and a method for producing a micromechanical component.

The present invention creates micromechanical components having a movable part that, relative to a holder of the micromechanical component, can be moved by a resonant oscillatory movement about a comparatively large “resonant” angle of rotation and at the same time by a quasi-static oscillatory movement about a large “static” angle of rotation. Moreover, through the present invention micromechanical components can also be realized in which the movable part can be moved by two resonant oscillatory movements. Through the present invention, micromechanical components can in particular be designed such that large amplitudes for the resonant oscillatory movement of the movable part can be achieved, and at the same time also a resetting force/spring resetting force that is as small as possible counteracts a constant deflection of the movable part by the quasi-static oscillatory movement. As is stated more precisely below, above all through an advantageous coupling/connection of the movable part to the respective suspension structure of the micromechanical component, a resonance increase can be produced during the resonant oscillatory movement of the movable part relative to the holder. The movable part can therefore be moved by comparatively large “resonant” and “static” angles of rotation about the two axes of rotation, thereby achieving an increase of a maximum possible angle of rotation for the micromechanical component.

As is stated more precisely below, the micromechanical components realized according to the present invention can have a comparatively simple design. The micromechanical components realized according to the present invention are therefore comparatively easy to produce. In addition, comparatively simple user electronics can be used to operate the micromechanical components realized according to the present invention.

The present invention also creates micromechanical components in which three degrees of rotational freedom are realized for moving the movable part relative to the holder. Moreover, for all three degrees of rotational freedom, relatively large “resonant” and/or “static” angles of rotation of the movable part can be carried out relative to the holder.

In an advantageous specific embodiment, the suspension structure includes at least one bending beam. The at least one bending beam can reliably be set into self-oscillation by the at least one actuator device, a bearing of the at least one oscillation point of the induced self-oscillations being easily ascertainable. Moreover, given a suspension structure having the at least one bending beam, oscillation node points of a plurality of self-oscillations can also be situated at the same location.

For example, the single bending beam of the suspension structure, or at least one of the bending beams of the suspension structure, can run without interruption along a specified beam longitudinal axis. The respective bending beam is thus comparatively easy to realize. For example, such a bending beam can be structured out from a semiconductor layer using easily realizable etching methods.

In a further advantageous specific embodiment, the single bending beam of the suspension structure, or at least one of the bending beams of the suspension structure, has an inner frame situated between a first beam segment and a second beam segment, on which frame the movable part is suspended. In particular, the first beam segment and the second beam segment can run along a first spatial direction, the movable part being suspended on the inner frame via the at least one spring, which extends along a second spatial direction running perpendicular to the first spatial direction. Such a suspension structure fashioned in this way is also easy to produce/etch, and ensures good movability of the movable part relative to the holder, for example in the first spatial direction and in the second spatial direction.

Likewise, the single bending beam of the suspension structure, or at least one of the bending beams of the suspension structure, can be fashioned with a meander shape. A meander-shaped bending beam can also be set into self-oscillations, the self-oscillations (due to the fact that the meander-shaped bending beam can be made long) counteracting a comparatively small resetting force. Although the meander-shaped bending beam for reducing the resetting force can be made comparatively long, a space-saving design is easy to realize at the micromechanical component.

The single bending beam of the suspension structure, or at least one of the bending beams of the suspension structure, can contact the holder with an anchoring region. Alternatively to this, the single bending beam of the suspension structure, or at least one of the bending beams of the suspension structure, can also be connected to the holder via at least one external spring.

The at least one external spring can for example be at least one torsion spring, at least one meander-shaped spring, at least one U-spring, and/or at least one double U-spring. In this way, a multiplicity of easily structurable external springs can be used to suspend the at least one bending beam on the holder. However, shapes deviating from the examples listed here are also possible for the at least one external spring.

The advantages described above can also be realized in an embodiment of the corresponding production method for a micromechanical component. It is to be noted that the production method can be further developed in accordance with the specific embodiments described above of the micromechanical component.

### BRIEF DESCRIPTION OF THE DRAWINGS

FIGS. 1a and 1b show a schematic representation of a first specific embodiment of the micromechanical component and a schematic reproduction of self-oscillations of its suspension structure.

FIGS. 2a through 2c show schematic representations of a second specific embodiment of the micromechanical component.

FIGS. 3a and 3b show schematic representations of a third specific embodiment of the micromechanical component.

FIG. 4 shows a schematic representation of a fourth specific embodiment of the micromechanical component.

FIGS. 5a and 5b show a schematic representation of a fifth specific embodiment of the micromechanical component and a schematic reproduction of self-oscillations of its suspension structure.

FIG. 6 shows a schematic representation of a sixth specific embodiment of the micromechanical component.

FIG. 7 shows a schematic representation of a seventh specific embodiment of the micromechanical component.

FIG. 8 shows a schematic representation of an eighth specific embodiment of the micromechanical component.

FIG. 9 shows a schematic representation of a ninth specific embodiment of the micromechanical component.

FIG. 10 shows a schematic representation of a tenth specific embodiment of the micromechanical component.

FIGS. 11a through 11d show schematic representations of various spring types that can be used as external springs for the micromechanical component.

FIG. 12 shows a schematic representation of an eleventh specific embodiment of the micromechanical component.

FIG. 13 shows a schematic representation of a twelfth specific embodiment of the micromechanical component.

FIG. 14 shows a schematic representation of a thirteenth specific embodiment of the micromechanical component.

FIG. 15 shows a schematic representation of a fourteenth specific embodiment of the micromechanical component.

FIG. 16 shows a schematic representation of a fifteenth specific embodiment of the micromechanical component. and

FIG. 17 shows a flow diagram for the explanation of a specific embodiment of the method for producing a micromechanical component.

### DETAILED DESCRIPTION

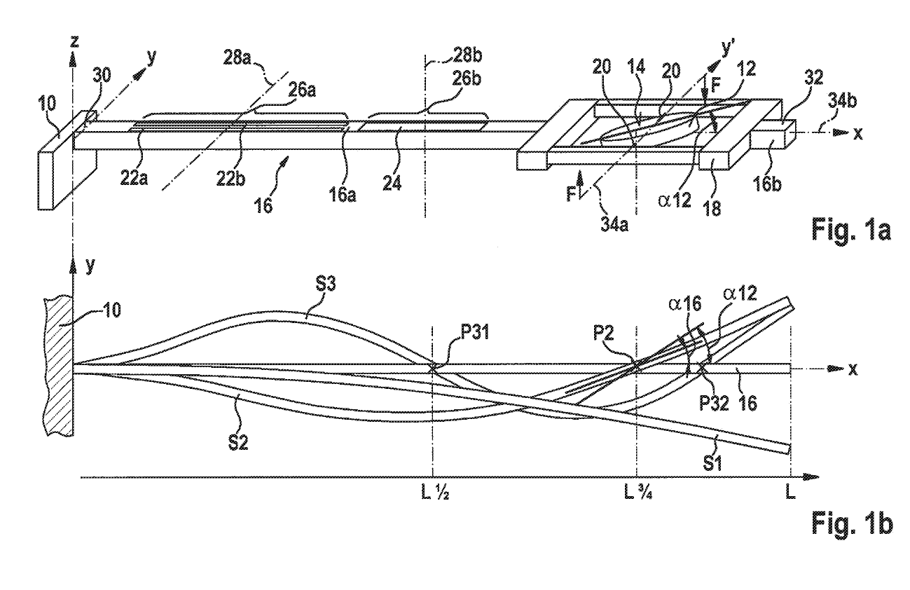

FIGS. 1a and 1b show a schematic representation of a first specific embodiment of the micromechanical component and a schematic reproduction of self-oscillations of its suspension structure.

The micromechanical component shown schematically in FIG. 1a has a holder 10 (shown only in part) and a part 12 that is movable relative to holder 10. In the specific embodiment of FIG. 1a, movable part 12 is a micro-mirror equipped with a mirror surface 14. Movable part 12 can however also have some other optically active surface, or, in at least one spatial direction, can be made throughout of an optically active material. Thus, movable part 12 can for example also be fashioned as a diffraction grating, a beam divider, a filter, and/or a prism.

Movable part 12 is suspended on holder 10 at least by a suspension structure 16. In the specific embodiment of FIG. 1a, suspension structure 16 is a bending beam 16 that includes an inner frame 18 situated between a first beam segment 16a and a second beam segment 16b. The first (bar-shaped) beam segment 16a and the second (bar-shaped) beam segment 16b run (straight/without deviation) along a first spatial direction x. Movable part 12 is suspended on inner frame 18 by at least one spring 20. The at least one spring 20 extends along a second spatial direction y′ running perpendicular to first spatial direction x. Specifically, in the specific embodiment of FIG. 1a, movable part 12 is suspended between two springs 20 in an interior space spanned by inner frame 18.

In the specific embodiment of FIG. 1a, bending beam 16 contacts holder 10 with an anchor region 30. For bending beam 16, a length L can be defined that extends along first spatial direction x from anchor region 30 up to an end segment 32 oriented away therefrom. Bending beam 16 shown in FIG. 1a can thus be designated a bending beam 16 clamped at one side. The one-sided suspension of bending beam 16/suspension structure 16 on holder 10 reduces a reset force that counteracts a deformation, bending, or torsion of bending beam 16/suspension structure 16, such as a torsion deflection of bending beam 16/suspension structure 16.

The micromechanical component also includes at least one actuator device 22a, 22b, and 24. The at least one actuator device 22a, 22b, and 24 is designed such that during an operation of the at least one actuator device 22a, 22b, and 24 at least one first subsegment 26a of suspension structure 16 can be set into a first harmonic oscillatory movement along a first axis of oscillation 28a. At the same time, by the operation of the at least one actuator device 22a, 22b, and 24 at least one second subsegment 26b of suspension structure 16 can be set into a second harmonic oscillatory movement along a second axis of oscillation 28b oriented at an incline to first axis of oscillation 28a. Axes of oscillation 28a and 28b are preferably oriented perpendicular to one another. In particular, in the specific embodiment of FIGS. 1a and 1b axes of oscillation 28a and 28b run perpendicular to first spatial direction x, first axis of oscillation 28a being oriented parallel to second spatial direction y′, and second axis of oscillation 28b being oriented perpendicular to first spatial direction and to second spatial direction y′. Moreover, an operation of the at least one actuator device 22a, 22b, and 24 is preferred in which the first oscillatory movement has a fixed phase relation to the second oscillatory movement. Preferably, the first oscillatory movement is phase-shifted by 90° relative to the second oscillatory movement.

This can also be described by saying that actuator device 22a, 22b, and 24 produces at least one oscillation of bending beam 16 in at least one plane of oscillation. The modes of oscillation induced by actuator device 22a, 22b, and 24 are shown for one plane of oscillation in FIG. 1b. However, actuator device 22a, 22b, and 24 also produces additional modes of oscillation in a plane of oscillation running perpendicular to the plane of the image of FIG. 1b.

The actuator principle used can also be described by saying that two translational sinusoidal movements/oscillatory movements of sub-segments 26a and 26b are produced, which are preferably oriented perpendicular to one another. As explained in more detail below, these movements/oscillatory movements of sub-segments 26a and 26b can be used to move movable part 12.

Using the at least one actuator device 22a, 22b, and 24, self-oscillations S1 through S3 can be induced in suspension structure 16/bending beam 16, in the manner described above. In particular, it is possible to induce both self-oscillations of suspension structure 16/bending beam 16 in a first plane spanned by first spatial direction x and first axis of oscillation 28a, and also self-oscillations S1 through S3 of suspension structure 16/bending beam 16 in a second plane spanned by first spatial direction x and second axis of oscillation 28b. (The actual oscillatory behavior of suspension structure 16/bending beam 16 corresponds to a superposition of the various induced self-oscillations.)

FIG. 1b schematically shows a first self-oscillation S1 of bending beam 16/suspension structure 16 in the second plane at a first natural frequency, a second self-oscillation S2 of bending beam 16/suspension structure 16 in the second plane at a second natural frequency, and a third self-oscillation S3 of bending beam 16/suspension structure 16 in the second plane at a third natural frequency. (For clarity, in FIG. 1b inner frame 18 is not shown.) First self-oscillation S1 has no oscillation node point. Second self-oscillation S2 has an oscillation node point P2 (which is situated at approximately ¾ L). For the third self-oscillation S3, a first oscillation node point P31 (at approximately ½ L) and a second oscillation node point P32 (at approximately 21/24 L) can be ascertained. (The positions of oscillation node points P2, P31, and P32 can shift as soon as deviations from an ideal beam are present.)

The length L of bending beam 16 (or, respectively, its width and/or its height) can in particular be selected such that oscillation node points P2, P31, and P32 of self-oscillations S1 through S3 in the second plane (spanned by first spatial direction x and second axis of oscillation 28b) coincide with oscillation node points of self-oscillations in the first plane (spanned by first spatial direction x and first axis of oscillation 28a). For example for oscillation node point P2 of second self-oscillation S2, this can be realized at ¾ L, or can be realized at ½ L and 21/24 L for the two oscillation node points P31 and P32 of third self-oscillation S3.

Movable part 12 is connected via the at least one spring 20 to at least one oscillation node point P2, P31, and P32 of at least one of the induced self-oscillations S1 through S3 of suspension structure 16. (The at least one spring 20 thus contacts the at least one oscillation node point P2, P31, and P32 of the induced self-oscillations S1 through S3 of suspension structure 16.) Preferably, movable part 12 is connected via the at least one spring 20 to at least one oscillation node point P2, P31, and P32 of at least one of the induced self-oscillations S1 through S3 of suspension structure 16 in the second plane (oriented perpendicular to second spatial direction y′). Preferably, a connection of movable part 12 via the at least one spring 20 is made at at least one point of bending beam 16/suspension structure 16 at which oscillation node points P2, P31, and P32 of self-oscillations S1 through S3 in the second plane coincide with oscillation node points of self-oscillations in the first plane.

In the specific embodiment of FIG. 1a, movable part 12 is connected via the at least one spring 20 to oscillation node point P2 of second self-oscillation S2 of the bending beam in the second plane. (Second spatial direction y′ runs through oscillation node point P2, shown in FIG. 1b, of second self-oscillation S2 of the bending beam in the second plane.) In the connection of movable part 12 to the at least one oscillation node point P2 of the at least one inducible self-oscillation of suspension structure 16/bending beam 16, it is taken into account that the position of the at least one oscillation node point P2 of the at least one inducible self-oscillation of suspension structure 16/bending beam 16 is as a rule influenced by the connection of movable part 12.

By the connection of movable part 12 via the at least one spring 20 to the at least one oscillation node point P2, P31, and P32 of at least one of the induced self-oscillations S1 through S3 of the bending beam/suspension structure 16, it can be reliably ensured that movable part 12 can be set into a resonant oscillatory movement about the second spatial direction y′, as a first axis of rotation 34a (relative to holder 10), by suspension structure 16 set into self-oscillations S1 through S3.

Moreover, the self-oscillations of bending beam 16/suspension structure 16 in the first plane (spanned by first spatial direction x and first axis of oscillation 28a) also produce a force F on movable part 12 that can be set into the resonant oscillatory movement (about a first axis of rotation 34a). Force F is proportional to the product of a first deflection amplitude of bending beam 16/suspension structure 16 in the first plane and a second deflection amplitude of bending beam 16/suspension structure 16 in the second plane. Moreover, force F is oriented perpendicular to the first plane. Force F therefore exerts a torque on movable part 12. Movable part 12 is therefore also (relative to holder 10) capable of being set, during its resonant oscillatory movement (about first axis of rotation 34a/second spatial direction y′), into a (preferably quasi-static) oscillatory movement/rotational movement about first spatial direction x (oriented at an incline to first axis of rotation 34a) as a second axis of rotation 34b. As is shown in FIG. 1a, the two axes of rotation 34a and 34b (or the two spatial directions x and y′) can be oriented perpendicular to one another.

In summary, movable part 12 can therefore be moved with a comparatively high frequency, which can be for example between 15-30 kHz, (relative to holder 10) about first axis of rotation 34a/second spatial direction y′, and with a significantly slower frequency, or a frequency of (almost) zero (relative to holder 10) about second axis of rotation 34b/first spatial direction x. Reference is made to the above-cited DE 10 2011 006 598 A1 for further explanation for the occurrence of the force F, which causes the quasi-static oscillatory movement of movable part 12 (relative to holder 10).

Preferably, movable part 12 is dimensioned such that its natural frequency, with regard to the resonant oscillatory movement about first axis of rotation 34a (or a multiple of this natural frequency), agrees with at least one natural frequency of a self-oscillation of bending beam 16/suspension structure 16 (or a multiple of such a natural frequency). Preferably, the respective natural frequency of movable part 12 (or a multiple of this natural frequency) agrees with at least one natural frequency of a self-oscillation of bending beam 16/suspension structure 16 in the second plane spanned by first spatial direction x and second axis of oscillation 28b (or with the multiple of such a natural frequency). In this way, an amplitude increase is easily realized when movable part 12 is moved about first axis of rotation 34a relative to holder 10. An angle α16 shown in FIG. 1b indicates a sinusoidal inclination of bending beam 16, set into its second self-oscillation S2 in the second plane, at oscillation node point P2. Moreover, in FIG. 1b an angle α12 is also shown that reproduces an inclination, simultaneously brought about, of the movable part about first axis of rotation 34a relative to its rest position/holder 10. It will be seen that, by a suitable definition of the natural frequency of movable part 12 regarding the resonant oscillatory movement about first axis of rotation 34a, an angle α12 can be brought about that is significantly increased relative to angle α16.

In the specific embodiment of FIG. 1, the micromechanical component has piezoelements 22a, 22b, and 24 as the at least one actuator device 22a, 22b, and 24. In order to induce the first harmonic oscillatory movement of first subsegment 26a along first axis of oscillation 28a, two (strip-shaped) piezoelements 22a and 22b are attached on a surface of first subsegment 26a oriented parallel to first axis of oscillation 28a, a first piezoelement 22a of the two piezoelements 22a and 22b being situated on a second side of the second plane. During operation, the two piezoelements 22a and 22b are controlled so as to be phase-shifted by 180°. The curvature that can be realized in this way of a respective side of the surface of first subsegment 26a oriented parallel to first axis of orientation 28a results in the first harmonic oscillatory movement of first subsegment 26a (or of bending beam 16).

It is to be noted that the design of the at least one actuator device 22a, 22b, and 24 as (strip-shaped) piezoelements 22a, 22b, and 24 is to be interpreted only as an example. For example, it is also possible to use at least one electrode statically acting interdigital electrode, at least one plate electrode, and/or at least one electromagnetic actuation to induce the oscillatory movements of subsegments 26a and 26b.

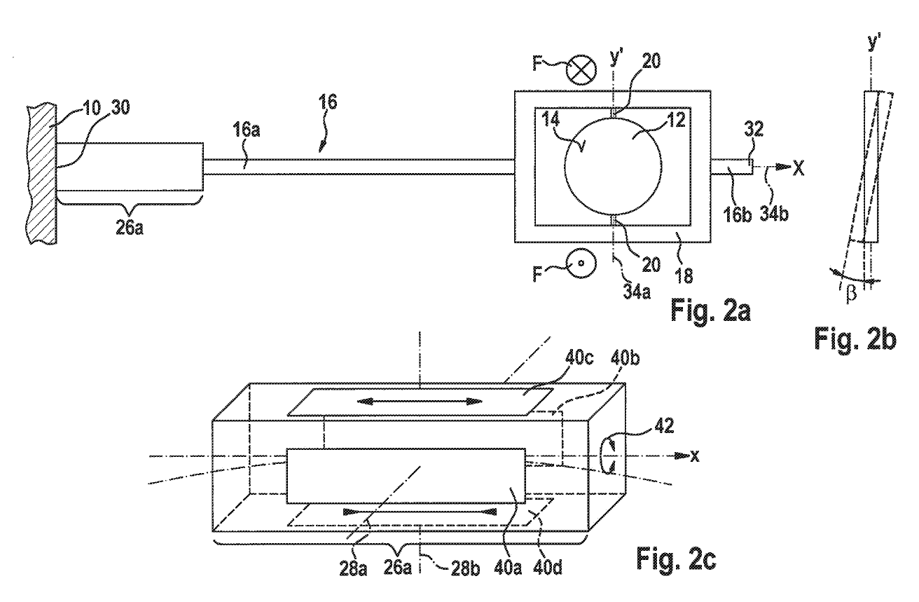

FIGS. 2a through 2c show schematic representations of a second specific embodiment of the micromechanical component.

The micromechanical component shown schematically in FIG. 2a in a side view oriented parallel to first spatial direction x, and shown schematically in FIG. 2b in a side view oriented parallel to second spatial direction y′, has four piezoelements 40a through 40d as the at least one actuator device 40a through 40d. As can be seen in FIG. 2c, the four piezoelements 40a through 40d are each situated on a (first) subsegment 26a of bending beam 16 in such a way that each outer side of the (first) subsegment 26a bears exactly one piezoelement 40a through 40d. A first pair of two piezoelements 40a and 40b of the four piezoelements 40a through 40d is situated on the outer sides of the (first) subsegment 26a oriented perpendicular to first axis of oscillation 28a.

A second pair of two piezoelements 40c and 40d of the four piezoelements 40a through 40d are situated on outer sides of (first) subsegment 26a, which run perpendicular to second axis of oscillation 28b.

The four piezoelements 40a through 40d are connected in such a way that, if a first piezoelement 40a and 40c of the same pair is compressed, a second piezoelement 40b and 40d of the same pair expands. Correspondingly, if first piezoelement 40a and 40c of the same pair expands, then second piezoelement 40b and 40d of the same pair is compressed. As a result, (first) subsegment 26a bends. If the two pairs of piezoelements 40a through 40d are controlled with a phase shift of 90°, there results a “hula hoop” movement of (first) subsegment 26a (or bending beam 16), indicated by arrow 42. The points of a mid-axis running centrically between the surfaces having piezoelements 40a through 40d execute an elliptical movement (preferably a circular movement) during the “hula hoop” movement. This can also be described by saying that (first) subsegment 26a is moved along first axis of oscillation 28a in the first harmonic oscillatory movement, and is moved along second axis of oscillation 28b, oriented at an incline to first axis of oscillation 28a, in the second oscillatory movement. In this way as well, the self-oscillations of bending beam 16 can be induced in the first plane, and self-oscillations S1 through S3 of bending beam 16 can be induced in the second plane. As described above, this brings about the resonant oscillatory movement of movable part 12 (relative to holder 10) about first axis of rotation 34a (or second spatial direction y′) and the quasi-static oscillatory movement of the movable part 12 (relative to holder 10) about second axis of rotation 34b (or first spatial direction x). The quasi-static oscillatory movement of movable part 12 is schematically shown (in section) in FIG. 2b by angle β.

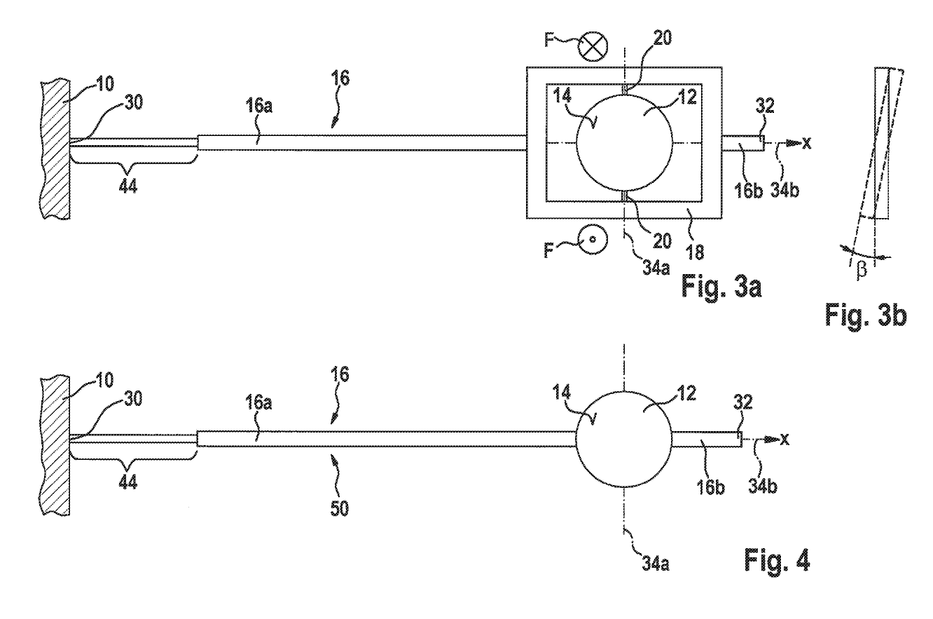

FIGS. 3a and 3b show schematic representations of a third specific embodiment of the micromechanical component.

In contrast to the specific embodiments described above, in the specific embodiment of FIGS. 3a and 3b bending beam 16 has a locally tapered segment 44 formed adjacent to holder 10.

Through the formation of such a locally tapered segment 44, a torsional rigidity of bending beam 16 can be reduced, in particular when there is a rotational movement of bending beam 16 about first spatial direction x.

FIG. 4 shows a schematic representation of a fourth specific embodiment of the micromechanical component.

The micromechanical component shown schematically in FIG. 4 has, as suspension structure 50, a bending beam 50 (clamped at one side) that runs without interruption (without deviation) along first spatial direction x, as a specified beam longitudinal axis. Bending beam 50 can also be designated straight (frameless) bending beam 50. Specifically, bending beam 50 can be understood as bar-shaped bending beam 50.

Movable part 12 is connected directly at at least one oscillation node point P2 of at least one of the self-oscillations S1 through S3 (inducible by the at least one actuator device (not shown)) of suspension structure 50/bending beam 50. In particular, movable part 12 can be fastened directly to an outer side of bending beam 50. As an example, in the specific embodiment of FIG. 4 movable part 12 is fastened directly to a connection point on an outer side of bending beam 50 oriented parallel to first spatial direction x (and perpendicular to second axis of rotation 28b).

The connection point between the movable part and bending beam 50 is preferably made small enough in surface that the oscillatory behavior of bending beam 50 is barely influenced or is not influenced. In the connection of movable part 12 at the at least one oscillation node point P2 of the at least one inducible self-oscillation of suspension structure 50/bending beam 50, it is taken into account that the position of the at least one oscillation node point P2 of the at least one inducible self-oscillation of suspension structure 50/bending beam 50 is as a rule influenced by the connection of movable part 12. Optionally, movable part 12 can also include a connection post that is anchored at the at least one oscillation node point P2 situated on the outer side of bending beam 50/suspension structure 50.

In the specific embodiment of FIG. 4 as well, two perpendicular translational sinusoidal movements (as oscillatory movements/external excitatory movements) are used to set bending beam 50 into its self-oscillations in the first plane and into its self-oscillations S1 through S3 in the second plane. Given a constant phase shift between the induced oscillatory movements, preferably 90°, averaged over time there results a torque about first spatial direction x. In the specific embodiment of FIG. 4 as well, movable part 12 can therefore be set into the resonant oscillatory movement about first axis of rotation 34a (with a comparatively high frequency) and into the quasi-static oscillatory movement/rotational movement about second axis of rotation 34b (with a significantly slower frequency) relative to holder 10.

In this case as well, large oscillatory amplitudes for movable parts 12 can be achieved, for which reason a light beam that can be deflected by movable part 12 can be deflected over a large angle.

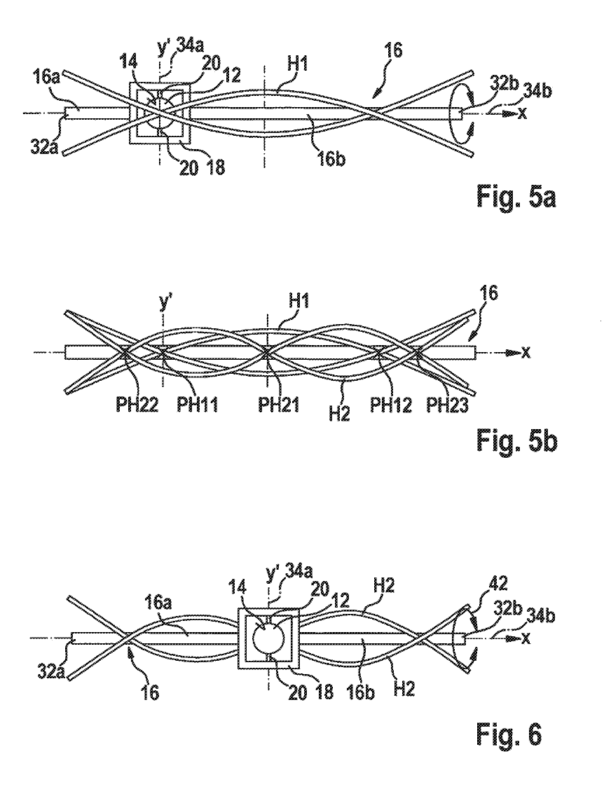

FIGS. 5a and 5b show a schematic representation of a fifth specific embodiment of the micromechanical component, and a schematic reproduction of self-oscillations of its suspension structure.

Bending beam 16 shown schematically in FIGS. 5a and 5b are present without clamping at holder 10. Instead, bending beam 16 as suspension structure 16 is connected to holder 10 at least via at least one external spring (not shown). A spacing between the two end segments 32a and 32b of bending beam 16, situated furthest from each other, along first spatial direction x defines length L of bending beam 16. In particular, the two end segments 32a and 32b of bending beam 16 can be free (i.e. without a mechanical contact with the at least one external spring). Bending beam 16 shown in FIGS. 5a and 5b can thus also be described as bending beam 16 free at both sides.

As can be seen on the basis of FIG. 5b, bending beam 16 free at both sides can also be set into its self-oscillations in the first plane and into its self-oscillations in its second plane. Of the inducible self-oscillations, in FIG. 5b a first hula hoop oscillation mode H1 is shown having two eccentrically situated oscillation node points PH11 and PH12, and a second hula hoop oscillation mode H2 is shown having a centrally situated oscillation node point PH21 and two eccentrically situated oscillation node points PH22 and PH23. (For clarity, in FIG. 5b internal frame 18 is not shown.)

In the specific embodiment of FIGS. 5a and 5b, movable part 12 is connected via the at least one spring 20 to one of the eccentrically situated oscillation node points PH11 or PH12 of the first hula hoop oscillation mode H1 of excited bending beam 16. In this way, the specific embodiment of FIGS. 5a and 5b also ensures the advantages described above.

In addition, movable part 12 can also be connected (as shown in FIG. 4) to bending beam 16 without the at least one spring 20.

FIG. 6 shows a schematic representation of a sixth specific embodiment of the micromechanical component.

In the micromechanical component shown schematically in FIG. 6, movable part 12 is connected via the at least one spring 20 to centrally situated oscillation node point PH21 of second hula hoop oscillation mode H2 of bending beam 16. (The position of inner frame 18, or the lengths of beam segments 16a and 16b, is/are adapted correspondingly.) The advantages described above can also be realized by such a connection.

For completeness, it is also to be noted that in this specific embodiment as well movable part 12 can be connected to bending beam 16 without the at least one spring 20.

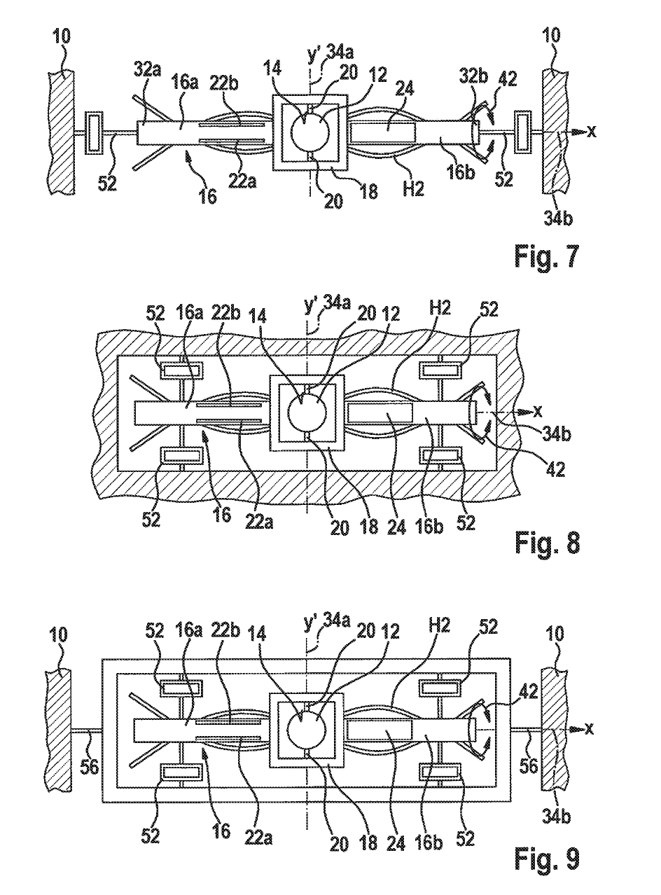

FIG. 7 shows a schematic representation of a seventh specific embodiment of the micromechanical component.

The micromechanical component of FIG. 7 is a development of the specific embodiment described above. The two end segments 32a and 32b of bending beam 16 of FIG. 7 are connected to holder 10 via a respective external spring 52. For each external spring 52, a spring line runs through its anchoring point on holder 10 and through its anchoring point on bending beam 16, along first spatial direction x.

Specifically, each of the external springs 52 is fashioned as a double U-spring 52. Each double U-spring 52 has two U-bends between a first spring longitudinal segment extending along the spring line and a second spring longitudinal segment extending along the spring line, fashioned relative to one another such that the U bends are oriented away from the spring line. The design described here of external springs 52 as double U-springs 52 is however to be interpreted only as an example.

By the connection at two sides of bending beam 16 to holder 10, using double U-springs 52, a comparatively soft suspension of bending beam 16 can be realized. This facilitates an excitation of hula hoop oscillation modes H1 and H2 described above, and of the torsion deflection.

FIG. 8 shows a schematic representation of an eighth specific embodiment of the micromechanical component.

In the specific embodiment of FIG. 8, bending beam 16 is connected to holder 10 via four external springs 52. Respectively two of the four external springs 52 are anchored to a respective beam segment 16a and 16b between end segment 32a or 32b fashioned thereon and internal frame 18 in such a way that the respective beam segment 16a or 16b is situated between the two external springs 52, and the spring lines of the two external springs 52 coincide. The spring lines of all four external springs 52 are oriented perpendicular to first spatial direction x.

The suspension of bending beam 16 by external springs 52 situated at a distance from end segments 32a and 32b additionally facilitates the inducement of hula hoop oscillation modes H1 and H2. In addition, the torsion deflection is also easily induced.

In the micromechanical component of FIG. 8 as well, external springs 52 are fashioned as double U-springs 52. However, such a design of external springs 52 is to be interpreted only as an example.

FIG. 9 shows a schematic representation of a ninth specific embodiment of the micromechanical component.

The micromechanical component of FIG. 9 is a development of the specific embodiment described above. In the specific embodiment of FIG. 9, bending beam 16 is connected to an external frame 54 via the four external springs 52. Moreover, two additional external springs 56, anchored on holder 10, extend along first spatial direction x at both sides on external frame 54. A “soft” spring suspension of the bending beam can also be realized in this way, in order to achieve a torsion deflection.

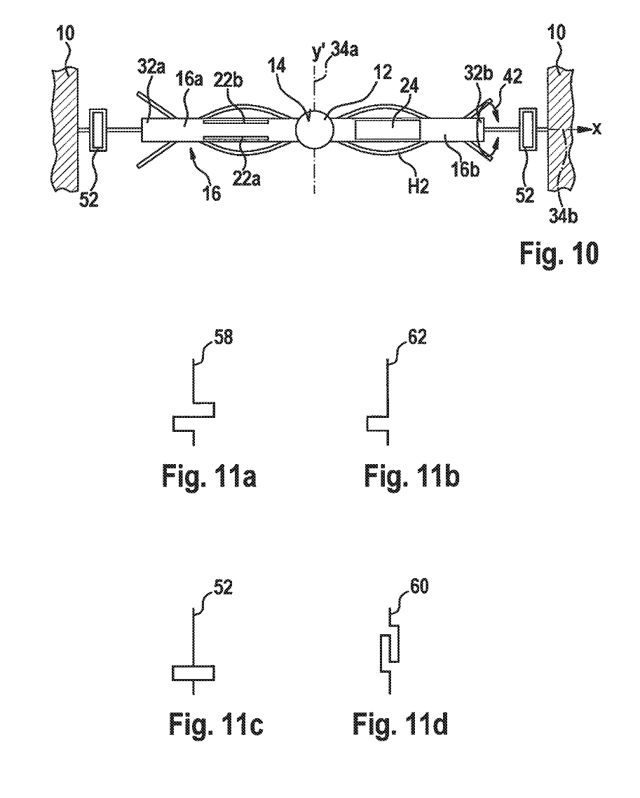

FIG. 10 shows a schematic representation of a tenth specific embodiment of the micromechanical component.

The specific embodiment of FIG. 10 has a bending beam 50 that runs without interruption (without deviation) along a first spatial direction x (as the specified beam longitudinal axis). Movable part 12 is connected directly to at least one oscillation node point PH21 of hula hoop oscillation mode H2 of suspension structure 50/bending beam 50. In particular, movable part 12 can be fastened directly to an external side of bending beam 50.

A respective external spring 52 is anchored at each of the two end segments 32a and 32b of bending beam 50. Via the two external springs 52, bending beam 50 is connected to holder 10. In the specific embodiment of FIG. 10 as well, external springs 52 are double U-springs 52 whose spring lines extend along first spatial direction x. However, such a realization of external springs 52 is to be interpreted only as an example.

Moreover, the specific embodiment of FIG. 10 can also be modified and developed corresponding to the micromechanical components of FIGS. 8 and 9 described above.

FIGS. 11a through 11d show schematic representations of various spring types that can be used as external springs for the micromechanical component.

As can be seen on the basis of FIGS. 11a through 11d, the at least one external spring can be at least one meander-shaped spring 58 and 60 (FIGS. 11a and 11d), at least one U-spring 62 (FIG. 11b), and/or at least one double U-spring 52 (FIG. 11c). In particular, various types of meander-shaped springs 58 and 60 can be used as the at least one external spring. In the specific embodiment of FIG. 11a, the bends point away from the spring lines of meander-shaped spring 58. In contrast, in the exemplary embodiment of FIG. 11d the bends of meander-shaped spring 60 point partly to its anchoring point on holder 10 and partly to its anchoring point on bending beam 16.

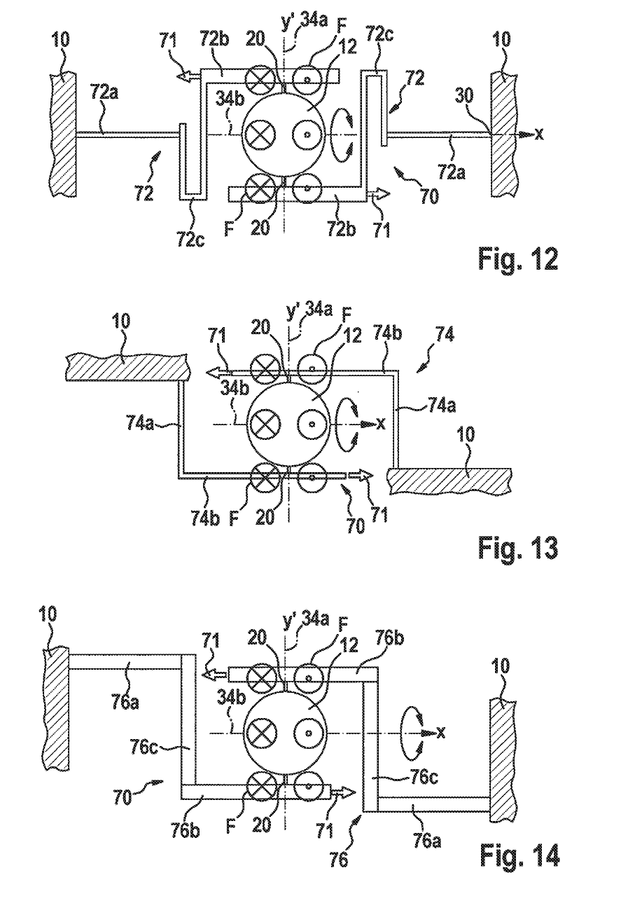

FIG. 12 shows a schematic representation of an eleventh specific embodiment of the micromechanical component.

The micromechanical component shown schematically in FIG. 12 has a suspension structure 70 of two bending beams 72. Each of the two bending beams 72 has a respective anchoring region 30 that contacts holder 10. Moreover, movable part 12 is connected via a respective spring 20 to each of the two bending beams 72, each of the springs 20 contacting the associated bending beam 72 at at least one oscillation node point of self-oscillations into which suspension structure 70 made up of the two bending beams 72 can be set. Movable part 12 is thus suspended at two sides, via suspension structure 70 made up of two bending beams 72, on holder 10. In this specific embodiment as well, the two springs 20 are oriented along second spatial direction y′.

The two bending beams 72 of suspension structure 70 are made with a meander shape. Each of the two bending beams 72 has a first end segment 72a whose anchoring region 30 contacts holder 10. Each of the springs 20 contacts at least one oscillation node point of self-oscillations, situated at a second end segment 72b of the associated bending beam 72. While the two first end segments 72a run along first spatial direction x, each of the two second end segments 72b (laterally offset to first end segments 72a) is oriented parallel to first spatial direction x. Each first end segment 72a is connected to the associated second end segment 72b via a bent intermediate segment 72c. However, it is to be noted that it is also possible for a plurality of bent intermediate segments 72c to be situated between a first end segment 72a and second end segment 72b of the same bending beam 72.

Despite the suspension at two sides of movable part 12, a “soft” suspension of movable part 12 of the micromechanical component of FIG. 12 is realized by a comparatively large overall length of the two meander-shaped bending beams 72, which is (nearly) equal to a sum of the lengths of first end segments 72a, the lengths of bent intermediate segments 72c, and the lengths of second end segments 72b. In particular, due to the meander-shaped realization of the two meander-shaped bending beams 72, the micromechanical component can be realized comparatively small despite the comparatively large overall length of the two meander-shaped bending beams 72.

Arrows 71 shown in FIG. 12 indicate oscillatory movements of the individual elements of the micromechanical component.

FIG. 13 shows a schematic representation of a twelfth specific embodiment of the micromechanical component.

In the specific embodiment of FIG. 13, movable part 12 is connected via a respective spring 20 to the two second end segments 74b of the two angled bending beams 74 of the micromechanical component. The two second end segments 74b each run perpendicular to second spatial direction y′ along which the two springs 20 extend. Each second end segment 74 contacts first end segment 74a of the same bending beam 74. However, the first end segments 74a are oriented at an incline to second end segments 74b. For example, there can be an angle of 90° between a second end segment 74b and an associated first end segment 74a of the same bending beam 74. A suspension structure 70 of the two angled bending beams 74 also ensures the advantages described above.

FIG. 14 shows a schematic representation of a thirteenth specific embodiment of the micromechanical component.

In the specific embodiment of FIG. 14, the two second end segments 76b of each of the two bending beams 76 of suspension structure 70 are oriented along a second axis of rotation 34b oriented perpendicular to second spatial direction y′. The first end segment 76a of each of the two bending beams 76 of suspension structure 70 is connected via an intermediate segment 76c to the associated second end segment 76b. Intermediate segment 76c can be oriented perpendicular to end segments 76a and 76b of the same bending beam 76. Bending beams 76 of the specific embodiment of FIG. 14 thus also have a meander-shaped (or bent) shape.

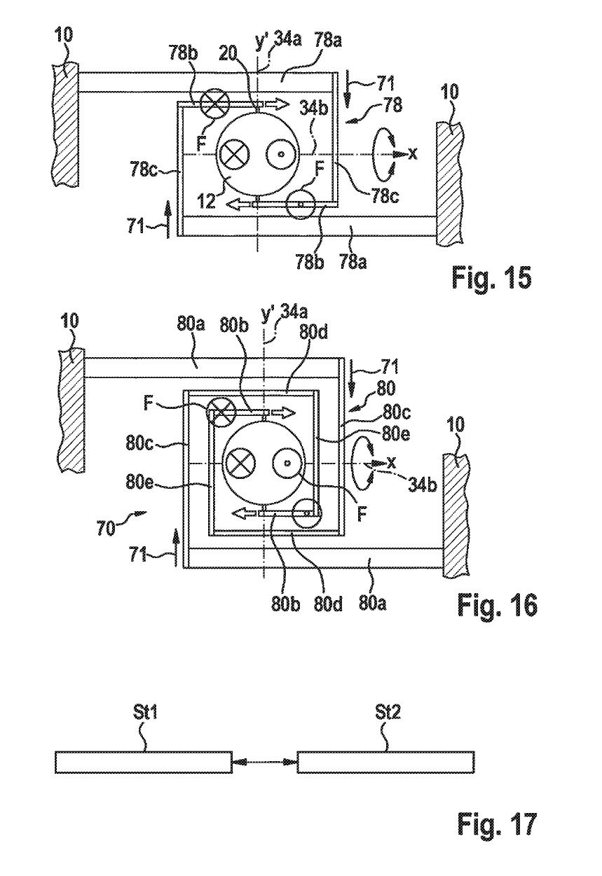

FIG. 15 shows a schematic representation of a fourteenth specific embodiment of the micromechanical component.

In the specific embodiment of FIG. 15, second end segment 78b of each bending beam 78 of suspension structure 70 is made shorter than first end segment 78a of the same bending beam 78. Moreover, second end segment 78b of each bending beam 78 runs parallel to a partial segment of first end segment 78a of the same bending beam 78. The two end segments 78a and 78b of a bending beam 78 are connected to one another via an intermediate segment 78c oriented perpendicular thereto.

The design shown in FIG. 15 of the two bending beams 78 of the micromechanical component permits comparatively large overall lengths of the two bending beams 78 despite a comparatively surface-saving design of the micromechanical component. A spring rigidity of the two bending beams 78 can thus be reduced without increasing a constructive space requirement of the micromechanical component.

FIG. 16 shows a schematic representation of a fifteenth specific embodiment of the micromechanical component.

In the specific embodiment of FIG. 16, three intermediate segments 80c through 80e are situated between each first end segment 80a and the associated second end segment 80b of the same bending beam 80, each of the three intermediate segments 80c through 80e being oriented so as to be inclined by an angle of 90° relative to the at least one adjacent intermediate segment 80c through 80e. Moreover, the intermediate segments 80c and 80e contacted by the two end segments 80a and 80b are oriented perpendicular to the contacted end segment 80a or 80b. This can also be described by saying that the two bending beams 80 of a micromechanical component of FIG. 16 are wound in a snail-shaped manner. Despite the comparatively large overall length of each bending beam 80 (which corresponds nearly to a sum of the individual lengths of the two end segments 80a and 80b and of the three intermediate segments 80c through 80e), in the specific embodiment of FIG. 16 movable part 12 requires only a comparatively small suspension surface. The micromechanical component of FIG. 16 is therefore made in a particularly space-saving and constructive-space-saving fashion.

The micromechanical components described above can be used for example in a scanner. Using such a scanner, a light beam, such as a laser beam, can be deflected with a fast frequency about a first specified axis and with a lower constant frequency, or statically (as a function of the excitation frequencies and their phase relations), about a specified second axis. Alternatively, the micromechanical components described above can also be used in micromirrors, optical switches, or optical multiplexers.

FIG. 17 shows a flow diagram explaining a specific embodiment of the method for producing a micromechanical component.

All micromechanical components described above can be produced by at least the method steps St1 and St2 described in the following. However, the practicability of the production method is not limited to the production of these micromechanical components.

In method step St1, a part that is movable relative to a holder of the micromechanical component is formed, the movable part being suspended (at least) via a suspension structure on the holder. In further method step St2, at least one actuator device is formed in such a way that, by the at least one actuator device, during operation of the micromechanical component, at least one first subsegment of the suspension structure is set into a first harmonic oscillatory movement along a first axis of oscillation, and the at least one first subsegment and/or at least one second subsegment of the suspension structure is set into a second harmonic oscillatory movement along a second axis of oscillation oriented at an incline to the first axis of oscillation. In this way, self-oscillations of the suspension structure are induced such that the movable part is set, by the suspension structure set into the self-oscillations, into a resonant oscillatory movement about a first axis of rotation and into a quasi-static oscillatory movement about a second axis of rotation oriented at an incline to the first axis of rotation. In order to realize the advantages explained above, in method step St1 the movable part is connected directly or via at least one spring to at least one oscillation node point of at least one of the induced self-oscillations of the suspension structure.

The method steps St1 and St2 can be carried out in any desired sequence, or can be carried out (at least in part) simultaneously.

1.-10. (canceled)

11. A micromechanical component, comprising:
a holder;
a part movable relative to the holder and suspended on the holder at least via a suspension structure; and
at least one actuator device, wherein:
through an operation of the at least one actuator device at least one of:
at least one first subsegment of the suspension structure is set into a first harmonic oscillatory movement along a first axis of oscillation, and
at least one of the at least one first subsegment and at least one second subsegment the suspension structure is set into a second harmonic oscillatory movement along a second axis of oscillation oriented at an incline to the first axis of oscillation, whereby self-oscillations of the suspension structure can be induced such that the movable part, in relation to the holder, can be set into a resonant oscillatory movement about a first axis of rotation and into a quasi-static oscillatory movement about a second axis of rotation oriented at an incline to the first axis of rotation by the suspension structure set into the self-oscillations, and
the movable part is connected one of directly and via at least one spring to at least one oscillation node point at least one of the induced self-oscillations of the suspension structure.

12. The micromechanical component as recited in claim 11, wherein the suspension structure includes at least one bending beam.

13. The micromechanical component as recited in claim 12, wherein the bending beam of the suspension structure runs without interruption along a specified beam longitudinal axis.

14. The micromechanical component as recited in claim 12, wherein the bending beam of the suspension structure includes an internal frame situated between a first beam segment and a second beam segment, and wherein the movable part is suspended on the frame.

15. The micromechanical component as recited in claim 14, wherein:
the first beam segment and the second beam segment run along a first spatial direction, and
the movable part is suspended on the frame via the at least one spring, and
the at least one spring extends along a second spatial direction running perpendicular to the first spatial direction.

16. The micromechanical component as recited in claim 12, wherein the bending beam of the suspension structure is made with a meander shape.

17. The micromechanical component as recited in claim 12, wherein the bending beam of the suspension structure contacts the holder with an anchoring region.

18. The micromechanical component as recited in claim 12, wherein the bending beam of the suspension structure is connected to the holder at least via at least one external spring.

19. The micromechanical component as recited in claim 18, wherein the at least one external spring includes at least one of at least one torsion spring, at least one meander-shaped spring, at least one U-spring, and at least one double U-spring.

20. A method for producing a micromechanical component, comprising:
forming a part that is movable relative to a holder of the micromechanical component;
suspending the movable part on the holder at least via a suspension structure; and
forming at least one actuator device, wherein:
through an operation of the at least one actuator device at least one of:
at least one first subsegment of the suspension structure is set into a first harmonic oscillatory movement along a first axis of oscillation, and
at least one of the at least one first subsegment and at least one second subsegment the suspension structure is set into a second harmonic oscillatory movement along a second axis of oscillation oriented at an incline to the first axis of oscillation, whereby self-oscillations of the suspension structure can be induced such that the movable part, in relation to the holder, can be set into a resonant oscillatory movement about a first axis of rotation and into a quasi-static oscillatory movement about a second axis of rotation oriented at an incline to the first axis of rotation by the suspension structure set into the self-oscillations, and
the movable part is connected one of directly and via at least one spring to at least one oscillation node point at least one of the induced self-oscillations of the suspension structure.
